(19) United States
(12) Patent Application Publication
(10) Pub. No.: US 2003/0007531 A1
(43) Pub. Date: Jan. 9, 2003

(54) Polarization controlled VCSELs using an asymmetric current confining aperture

(75) Inventor: Thomas Aggerstam, Solna (SE)

Correspondence Address: LAW OFFICE OF LAWRENCE E LAUBSCHER, JR, 1160 SPA RD, SUITE 2B, ANNAPOLIS, MD, 21403, US

(73) Assignee: Zarlink Semiconductor AB, Jarfalla (SE)

(21) Appl. No.: 10/180,790

(22) Filed: Jun. 25, 2002

(30) Foreign Application Priority Data
Jul. 3, 2001 (GB) 0116192.6

(51) Int. Cl. H01S 5/00; H01S 3/08

(52) U.S. Cl. 372/46; 372/96

(57) ABSTRACT

A vertical cavity surface emitting laser (VCSEL) having asymmetrical optical confinement is described. Polarization of VCSELs having symmetrical structures tend to be unpredictable and switchable. The VCSEL of the present invention has vertically etched apertures into the top bragg mirror in order to confine the optical path into an asymmetric structure. This has the effect of locking polarization into a fixed mode.

### FIELD OF THE INVENTION

This invention relates to a vertical cavity surface emitting laser (VCSEL) and more particularly to a VCSEL having an asymmetric optical confinement structure for polarization control and stabilization.

### BACKGROUND

Vertical cavity surface emitting lasers have gained significant importance in the field of optical communications. The high switching speed offered by semiconductor lasers employing, for example, III-V alloy compounds have made such devices a logical choice for optical transmitters. For several reasons including; reliability, ease of coupling, and testing, VCSELs have gained acceptance over the more conventional edge emitting devices. VCSELs are typically fabricated using well known planar processes and equipment and are well suited for integration with other active and passive components.

Typically, VCSELs have a common back contact and an apertured contact on the emitting face with the emission from the optical device exiting through the aperture. The contact aperture is usually circular as this is better suited for alignment with optical fibers.

Polarization of the light from such standard VCSELs is unpredictable as it tends to be randomly oriented from one device to another. Further, polarization may switch in operation particularly at high speeds. The polarization of light emitting from a VCSEL can be important especially when used in conjunction with polarization sensitive components and efforts have been made in an attempt to tailor or control VCSEL polarization.

In an article published by Fiedler et al. entitled “High Frequency Behaviour of Oxidized Single-Mode Single Polarization VCSELs with Elliptical Current Aperture”, Lasers and Electro-Optic Society annual meeting 1996 IEEE volume 1, 1996, pages 211 to 212 there is discussed a technique wherein oxidized VCSELs are provided with eleptical current apertures in an effort to control polarized single mode light emission.

An article entitled “Impact of In-Plane Anistropic Strain on the Polarization Behavior of Vertical-Cavity Surface-Emitting Lasers” by Panajotov et al. (Applied Physics Letters, Volume 77, Number 11, Sept. 11, 2000) discloses an externally induced in-plane anisotropic strain applied to a VCSEL in order to demonstrate the presence of switching between two fundamental modes with orthogonal linear polarization.

Externally applied strain or stress to control polarization of VCSELs was also described in U.S. Pat. No. 6,188,711 to Corzine et al.

U.S. Pat. No. 6,002,705 which issued Dec. 14, 1999 to Thornton describes wave length and polarization multiplexed vertical cavity surface emitting lasers in which stress inducing elements are disposed on a free surface of the laser device. The stress inducing elements are made of a material having a higher coefficient of thermal expansion than the material which comprises the surface layer of the laser device.

U.S. Pat. No. 5,953,962 which issued Sep. 14, 1999 to Pamulapati et al. describes a strain induced method of controlling polarization states in VCSELs. In the 5,953,962 patent the VCSEL is eutectically bonded to a host substrate which has a predetermined anisotropic coefficient of thermal expansion. During the forming process a uniaxial strain is induced within the laser cavity.

U.S. Pat. No. 6,154,479 which issued Nov. 28, 2000 to Yoshikawa et al. discloses a VCSEL in which control of the polarization direction is effected by limiting the cross sectional dimension of the top mirror so as to limit only a single fundamental transverse mode in the wave guide provided by the mirror. A non-circular or eliptical device is created so as to control the polarlization.

U.S. Pat. No. 5,995,531 which issued Nov. 30, 1999 to Gaw et al. also discloses an elliptical cross sectional top mirror which is formed into a ridge with the ridge being etched down into an ion implantation region to form an elongated shape so as polarize light emitted by the device. It is also known in the prior art to use rectangular air-post structures, asymmetric oxide apertures and an elliptical hole on the bottom emitting laser as ways of controlling polarization.

All of the above methods involve complex fabrication and/or processing steps and what is needed is a simple technique of controlling and stabilizing polarization of VCSELs.

The present invention solves the aforementioned problem of polarization switching particularly when the VCSEL is operated with large modulation signals, by modifying the symmetry of the optical confining aperture.

Therefore, in accordance with a first aspect of the present invention there is provided a vertical cavity surface emitting laser (VCSEL) comprising: a bottom mirror structure; a top mirror structure; an active layer sandwiched between the top mirror structure and the bottom mirror structure; electrical contacts associated with the top mirror structure and the bottom mirror structure; and confinement means in the top mirror structure to confine optical output from the VCSEL to an asymmetric path.

In accordance with a second aspect of the present invention there is provided a method of fabricating a vertical cavity surface emitting laser (VCSEL) for polarization control comprising: providing a VCSEL having a bottom mirror structure; a top mirror structure; an active layer sandwiched between the top mirror structure and the bottom mirror structure; and electrical contacts associated with the top mirror structure and the bottom mirror structure; and creating confinement means in the top mirror structure to confine optical output from the VCSEL to an asymmetric path.

### BRIEF DESCRIPTION OF THE DRAWINGS

The invention will now be described in detail with reference to the attached figures wherein:

FIG. 1 is a cross sectional view of a VCSEL according to one aspect of the present invention;

FIG. 2 shows the principle of operation of a light emitting device generating spontaneous emission;

FIG. 3 shows the principle of action of a light emitting device resulting in stimulated emission as used in laser devices;

FIG. 4 is a cross sectional view of a VCSEL showing the holes injected on the p-side, electrons injected on the n-side and radiative recombination in the active region;

FIG. 5 shows the oxidization rate as a function of aluminum concentration in an AlGaAs alloy;

FIG. 6 is a top view of a VCSEL structure including etched holes used to create an asymmetric optical aperture; and

FIG. 7 is a top view of a pixel structure illustrating an alternate configuration for an asymmetric optical aperture.

### DETAILED DESCRIPTION OF THE INVENTION

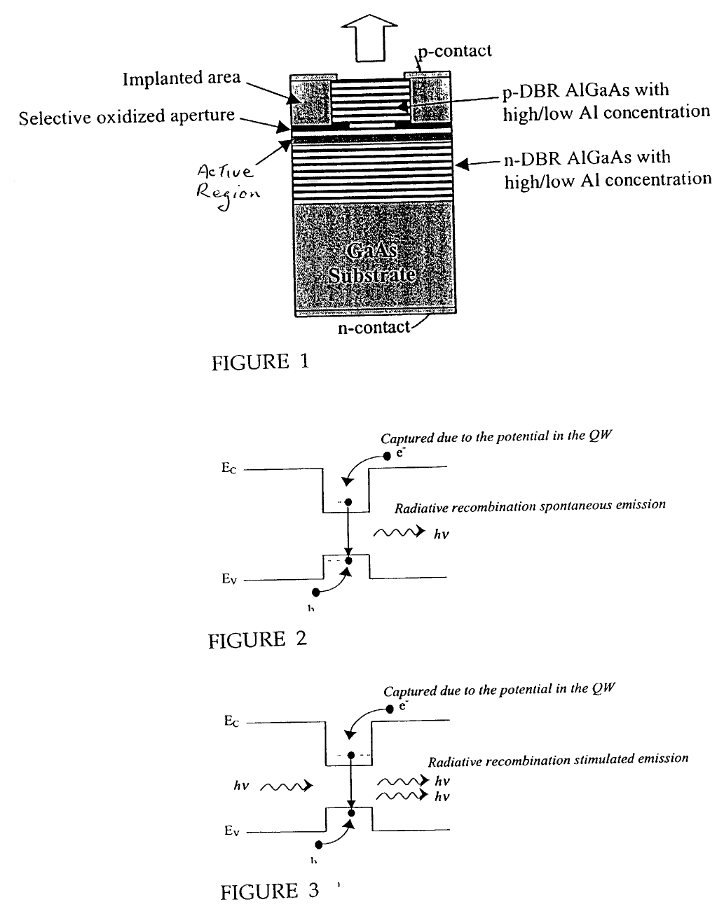

FIG. 1 illustrates the basic construction of a VCSEL, for example, an AlGaAs VCSEL. Although FIG. 1 refers to a specific VCSEL structure and in particular an 850 nm p-up configuration the VCSEL could consist of other material systems for use in emitting at other wavelengths. It is well known that different laser structures and materials can be used to tailor the output wavelength of the emission. Further, the structure shown in FIG. 1 has a p-type top DBR whereas it is also possible that the top DBR would be n-type. In the embodiment of FIG. 1, the VCSEL structure is grown on a gallium arsenide substrate by well known techniques such as metal organic vapor phase epitaxy. Preferably the structure is grown in one single epitaxial run. The gallium arsenide substrate in a typical structure is n-type, as is the bottom distributed bragg reflector (DBR) also known as a Bragg mirror. The n-DBR consists of λ/4 AlₓGa₁₋ₓAs alternating high and low index layers. It is to be understood that the quarter wavelength or λ/4 as shown is the nominal value for the optical path length. This length could also be written as L=λ/4+n×λ/2 where n is an integer and L is the optical path length. The active layer on top of the bottom mirror is a m×λ/2, long cavity comprising multiple quantum wells. In a particular embodiment of the invention the bottom mirror is a 1λ long AlGaAs/GaAs graded index separate confining heterostructure (GRINSCH), multi quantum-well (MQW) region. A second Bragg mirror or DBR of p-type AlGaAs with high low aluminum concentration is grown on top of the active layer. An apertured p-type contact is created on the top mirror and an n-contact is plated on the gallium arsenide substrate. Typically, an ion implanted area is created in the p-DBR to confine the current path between the p-contact and the n-contact. Also shown in FIG. 1 is a layer identified as selective oxidized aperture which is one layer of the p-DBR which has a higher aluminum concentration then the other layers in the stack. The reason for this oxidizable layer will be described later.

By way of explanation only, FIGS. 2 and 3 illustrate the principle of the recombination mechanism occurring in the quantum well active region. When the p- and n-type carriers reach the active region they recombine with the emission of a photon as a result. Phonons are localized quanta of energy and travel through space in a wave like fashion. The energy transported by a large number of photons is, on an average, equal to the energy transferred by a classical electro magnetic wave. This duality is in quantum mechanics referred to as “the particle wave duality”. The electron and hole functions are governed by the Schrodinger equation. The solution to this equation yields the energy states allowed to be occupied by the particles. The coupling strength between these states determines the transition probability there between. With solely the electron/hole coupling present the transition occurs spontaneously as shown in FIG. 2. However, with the influence of an electromagnetic (optical) field with a determined phase, a second coupling becomes present. This coupling stimulates the electrons to recombine with the holes that emit a photon, as shown in FIG. 3, with exactly the same energy and phase as the electromagnetic field. This recombination process is the one produced in a laser and is referred to as stimulated emission.

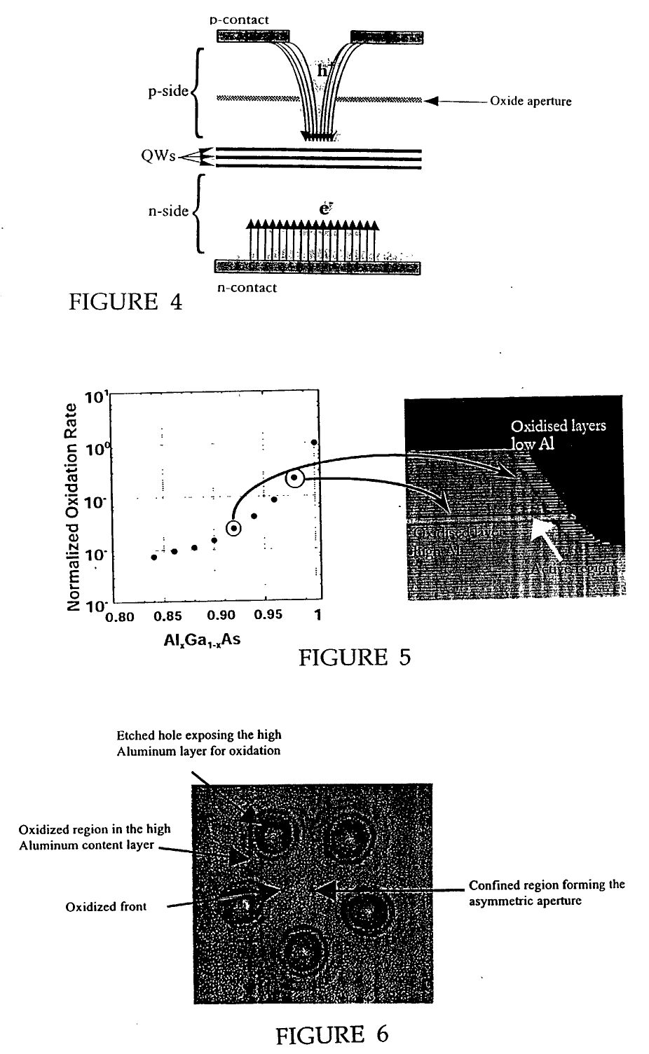

FIG. 4 shows graphically the electron and hole flow from p and n-type contacts to the quantum well active region. The carriers are injected into the structure through the p and n-contacts. Hole injection is from the p-side while electron injection is from the n-side and the radiation recombination occurs in the active region. Also shown in FIG. 4 is the aforementioned oxide aperture which will now be discussed in greater detail.

It has been established that AlGaAs layers with a high aluminum content can be oxidized in the presence of heated vapour. Typically, an oxidizable layer is grown in the top DBR and then the DBR is etched to form a mesa to thereby expose the edge of the oxidizable layer. The device is then treated in a vapor atmosphere at an elevated temperature and the oxidization proceeds from the exposed area towards the center. By selecting an appropriate treatment time the oxidized layer will proceed inwardly from all sides leaving a central unoxidized layer. This central unoxidized aperture is used to provide a current confinement region.

In U.S. Pat. No. 5,896,408 to Corzine et al. the oxidized layer is formed by etching apertures from the top surface of the device down to the oxidizable layer and then exposing the structure to a vapor atmosphere. By forming a pattern of etched apertures down to the oxidizable layer the current confining region is controlled.

The present invention utilizes the concept of using strategically located, etched holes to create an asymmetrical optical confining aperture to control or select the polarization mode.

In a particular embodiment the etched holes into the top DBR sufficiently disrupts the symmetry of the optical aperture to control the polarization. In a preferred embodiment the etched holes extend down to the oxidizable layer and the structure is then subjected to the aforementioned vapor treatment in order to create an oxidized region between the etched holes to thereby create an asymmetrical optical aperture as shown in FIG. 6.

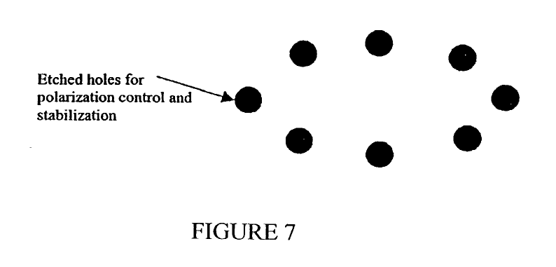

FIG. 7 illustrates an alternate embodiment of the etched holes for use in polarization control and stabilization. In the embodiment of FIG. 7 the aperture does not have holes placed at the same radius. This is only one example of numerous possible configurations for the etched holes. It will also be apparent to one skilled in the art that the holes do not all need to be circular or of the same size.

As indicated previously the oxidizable layer contains a higher aluminum content than the usual layers of the mirror structure. As shown in FIG. 5 the oxidization rate increases as a function of the aluminum concentration in the aluminum gallium arsenide alloy.

In the embodiment wherein the etched holes alone are used to create an asymmetric electrical and optical confinement zone, the number and location of the holes is important. These holes are located utilizing photolithographic techniques. Etchants to etch holes into the AlGaAs material are well known and not described here.

In summary, an electrical confining aperture is typically formed by selectively implanting the semiconductor material in the p-DBR to form an insulating region around a conducting symmetric aperture. This insulating region in a typical VCSEL confines the electrical field but does not confine the optical field. By etching vertical holes into this insulating implanted region the periphery of the holes thus created confine the optical mode in a way which disrupts the symmetry of the optical mode. Both the electrical and optical confinement region would be further improved using the aforementioned oxidizing process. As discussed in FIG. 6 the holes are formed to expose the high aluminum content layer for use in the oxidation process. To be able to oxidize the exposed holes adds considerably to the effectiveness of the process.

Although particular embodiments of the invention have been described and illustrated it will be apparent to one skilled in the art that numerous changes can be made. It is intended, however, that such changes will, within the true scope of the invention as defined by the appended claims.

1. A vertical cavity surface emitting laser (VCSEL) comprising:
a bottom mirror structure;
a top mirror structure;
an active layer sandwiched between the top mirror structure and the bottom mirror structure;
electrical contacts associated with the top mirror structure and the bottom mirror structure; and
confinement means in the top mirror structure to confine optical output from the VCSEL to an asymmetric path.

2. A VCSEL as defined in claim 1 wherein said confinement means is a plurality of etched apertures into the top mirror structure.

3. A VCSEL as defined in claim 2 having an ion implanted electrical confinement aperture to confine current flow between said electrical contacts.

4. A VCSEL as defined in claim 3 wherein said bottom mirror structure is an n-doped distributed Bragg reflector and said top mirror structure is a p-doped distributed Bragg reflector.

5. A VCSEL as defined in claim 3 wherein said bottom mirror structure is a p-doped distributed Bragg reflector and said top mirror structure is a n-doped distributed Bragg reflector.

6. A VCSEL as defined in claim 4 wherein said active layer is equal to m×λ/2 where m is an integer.

7. A VCSEL as defined in claim 4 wherein said active layer is a one wavelength long, graded index separate confining hetero-structure, multi-quantum well structure.

8. A VCSEL as defined in any proceeding claim wherein the top and bottom mirrors consist of Bragg reflectors having layers of alternating high and low refractive index where the length of each layer is equal to λ/4+n×λ/2 where n is an integer.

9. A VCSEL as defined in claim 5 wherein said top and bottom mirrors consist of quarter wavelength layers of alternating high and low refractive index.

10. A VCSEL as defined in claim 6 wherein said active layer comprises a AlGaAs/GaAs structure and said mirrors comprise layers of AlGaAs.

11. A VCSEL as defined in any preceding claim wherein said top mirror contains at least one layer of an oxidizable material.

12. A VCSEL as defined in claim 11 wherein said oxidizable layer comprises a AlGaAs layer having a higher concentration of Al than the rest of the mirror.

13. A method of fabricating a vertical cavity surface emitting laser (VCSEL) for polarization control comprising:
providing a VCSEL having a bottom mirror structure; a top mirror structure; an active layer sandwiched between the top mirror structure and the bottom mirror structure; and electrical contacts associated with the top mirror structure and the bottom mirror structure; and
creating confinement means in the top mirror structure to confine optical output from the VCSEL to an asymmetric path.

14. The method as defined in claim 13 wherein said top mirror structure includes a layer of oxidizable material.

15. The method as defined in claim 14 wherein said confinement means is created by etching a plurality of apertures in a predefined pattern into the top mirror structure.

16. The method as defined in claim 15 wherein said apertures are etched down to at least said oxidizable layer.

17. The method as defined in claim 16 including the step of exposing said apertures to a vapor process to thereby selectively oxidize said oxidizable layer.

18. The method as defined in claim 15 wherein said apertures are in a circular pattern.

19. The method as defined in claim 15 wherein said apertures are in an elliptical pattern.
